(19) United States
(12) Patent Application Publication
(10) Pub. No.: US 2015/0251228 A1
(43) Pub. Date: Sep. 10, 2015

(54) WAFER HOLDER CLEANING APPARATUS AND FILM DEPOSITION SYSTEM INCLUDING THE SAME

(71) Applicant: SAMSUNG ELECTRONICS CO., LTD., Suwon-si (KR)

(72) Inventors: Sang Kyu BANG, Hwaseong (KR); Sung Don KWAK, Suwon (KR); Choo Ho KIM, Yongin (KR); Won Soo JI, Hwaseong (KR)

(21) Appl. No.: 14/719,301

(22) Filed: May 21, 2015

Related U.S. Application Data
(62) Division of application No. 13/843,203, filed on Mar. 15, 2013.

(30) Foreign Application Priority Data
Nov. 14, 2012 (KR) 10-2012-0128614

(51) Int. Cl. B08B 5/02; H01L 21/687; H01L 21/673; H01L 21/677; B08B 1/00; H01L 21/67

(52) U.S. Cl. CPC B08B 5/02; B08B 1/002; H01L 21/6719; H01L 21/67346; H01L 21/67748; H01L 21/68764

(57) ABSTRACT

There are provided a wafer holder cleaning apparatus and a film deposition system including the same, the wafer holder cleaning apparatus including a housing part including an entrance into and out of which a wafer holder is carried, a door part selectively opening and closing the entrance, a support part provided within the housing part and having the wafer holder disposed thereon, the wafer holder being carried into the housing part through the entrance, and a cleaning part cleaning a surface of the wafer holder.

### CROSS-REFERENCE TO RELATED APPLICATIONS

This is a Divisional of application Ser. No. 13/843,203, filed on Mar. 15, 2013, which claims the benefit of Korean Patent Application No. 10-2012-0128614 filed on Nov. 14, 2012, which is incorporated herein by reference.

### BACKGROUND OF THE INVENTION

1. Field of the Invention

The inventive subject matter relates to a wafer holder cleaning apparatus and a film deposition system including the same.

2. Description of the Related Art

In a metal organic chemical vapor deposition (MOCVD) apparatus, among vapor deposition apparatuses used as an apparatus for growing a single crystal of a semiconductor layer forming a light emitting diode, a sapphire wafer is placed on a satellite disk, a type of a wafer holder, to rotate while a reaction gas is introduced thereto, such that a single crystal is grown on the wafer.

In this case, the satellite disk is disposed on a susceptor, and the susceptor rotates using a motor to maintain a gradient of a heat source in a horizontal state, thereby allowing a single crystal layer to be grown uniformly.

However, cleaning operations are required due to foreign objects (GaN, Mg, AlGaN or the like) which may be adhered to a surface of the satellite disk after every growth period, and in a case in which cleaning operations are manually performed, a reduction in apparatus efficiency and a reduction in available labor force may be caused.

### SUMMARY OF THE INVENTION

An aspect of the inventive subject matter provides a wafer holder cleaning apparatus capable of automatically performing a previously manually performed cleaning operation on a wafer holder, and a film deposition system including the same.

According to an aspect of the inventive subject matter, there is provided a wafer holder cleaning apparatus including: a housing part including an entrance into and out of which a wafer holder is carried; a door part selectively opening and closing the entrance; a support part provided within the housing part and having the wafer holder disposed thereon, the wafer holder being carried into the housing part through the entrance; and a cleaning part cleaning a surface of the wafer holder.

The cleaning part may include a spraying nozzle spraying gas onto the wafer holder.

The spraying nozzle may spray nitrogen (N₂) gas onto the surface of the wafer holder.

The cleaning part may include a bush brushing the surface of the wafer holder.

The door part may include a door opening or closing the entrance and an actuator moving the door to enable the entrance to be opened or closed.

The door part may further include at least a pair of guide members guiding the moving of the door.

The support part may include a base clamping and declamping the wafer holder and a driving unit rotatably driving the base.

The wafer holder cleaning apparatus may further include a control part controlling operations of the door part, the support part, and the cleaning part.

The wafer holder cleaning apparatus may further include a ventilation part provided in the housing part and ventilating an interior of the housing part.

According to another aspect of the inventive subject matter, there is provided a film deposition system, including a film deposition apparatus including a susceptor having a plurality of wafer holders disposed thereon; a transfer apparatus carrying the wafer holders out of the film deposition apparatus and carrying the wafer holders into the film deposition apparatus; and a cleaning apparatus including a support part having the wafer holders disposed thereon, the wafer holders being carried out through the transfer apparatus.

The film deposition system may further include a chamber connected to the film deposition apparatus and receiving the transfer apparatus therein.

The transfer apparatus may carry the wafer holders out of the film deposition apparatus through a slit valve provided between the chamber and the film deposition apparatus to carry the wafer holders into the cleaning apparatus, and may carry the wafer holders out of the cleaning apparatus to carry the wafer holders into the film deposition apparatus.

The cleaning apparatus and the transfer apparatus may be disposed within the chamber.

The cleaning apparatus may include a housing part having the support part disposed therein and including an entrance which the transfer apparatus accesses; a door part selectively opening and closing the entrance; and a cleaning part cleaning surfaces of the wafer holders.

The film deposition system may further include a wafer separation apparatus separating wafers from the wafer holders carried out of the film deposition apparatus.

### BRIEF DESCRIPTION OF THE DRAWINGS

The above and other aspects, features and other advantages of the inventive subject matter will be more clearly understood from the following detailed description taken in conjunction with the accompanying drawings, in which:

FIG. 1 is a perspective view schematically showing a wafer holder cleaning apparatus according to an embodiment of the inventive subject matter;

FIG. 2 is a cross-sectional view of FIG. 1, taken along line A-A;

FIGS. 3A and 3B are a perspective view and a cross-sectional view schematically showing a state in which an entrance is opened by a door part, from FIG. 1;

FIGS. 4A and 4B are a perspective view and a cross-sectional view schematically showing a state in which the entrance is closed by the door part, from FIG. 1;

FIG. 5A is a plan view schematically showing a state before a second door closely contacts the entrance;

FIG. 5B is a plan view schematically showing a state in which the second door closely contacts the entrance;

FIGS. 6 and 7 are plan views schematically showing a cleaning part from FIG. 1;

FIGS. 8A and 8B are a plan view and a cross-sectional view schematically showing a film deposition system according to an embodiment of the inventive subject matter;

FIG. 9A is an enlarged cross-sectional view schematically showing portion B, from FIG. 8B;

FIG. 9B is a plan view schematically showing a state in which a wafer holder of FIG. 9 rotates and revolves; and

FIGS. 10A through 15B are views schematically showing operational states of the film deposition system in a stepwise manner according to an embodiment of the inventive subject matter.

### DETAILED DESCRIPTION OF THE EMBODIMENTS

Hereinafter, embodiments of the inventive subject matter will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

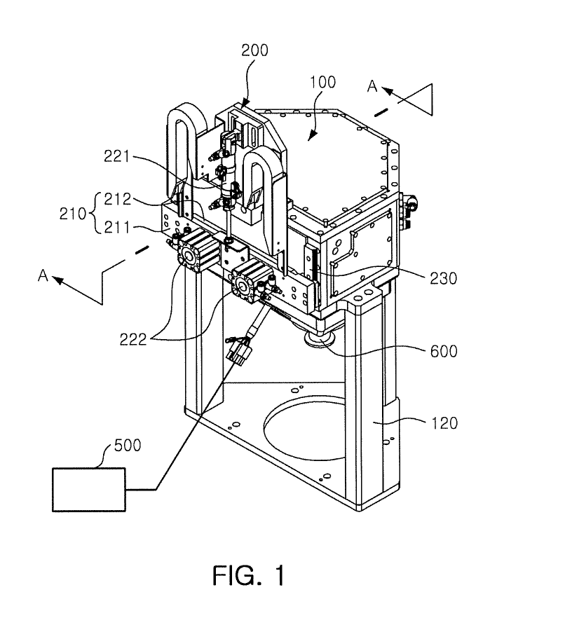

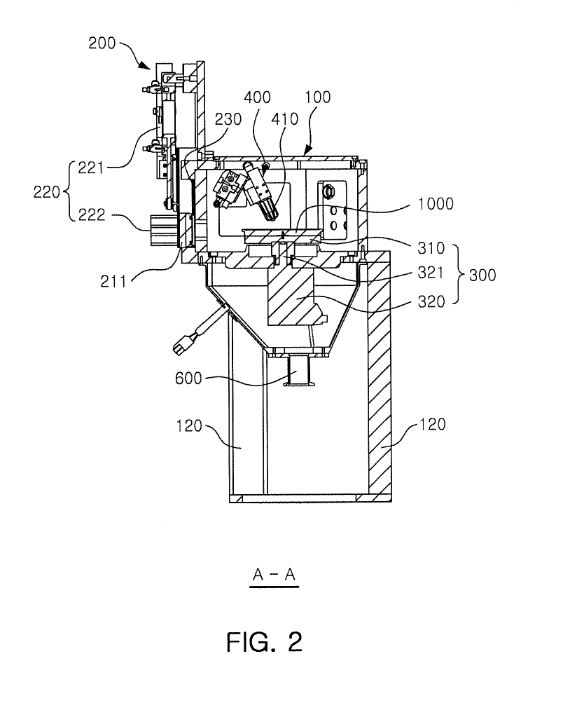

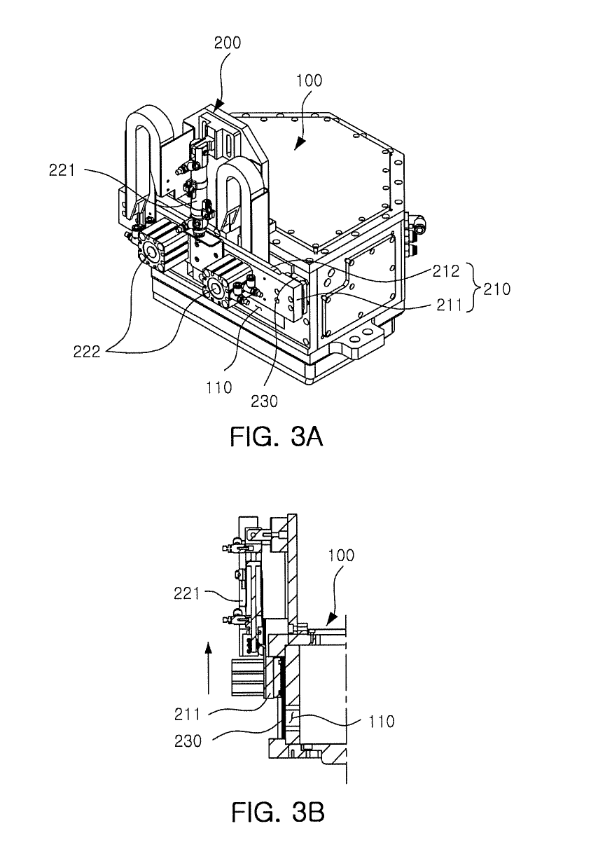

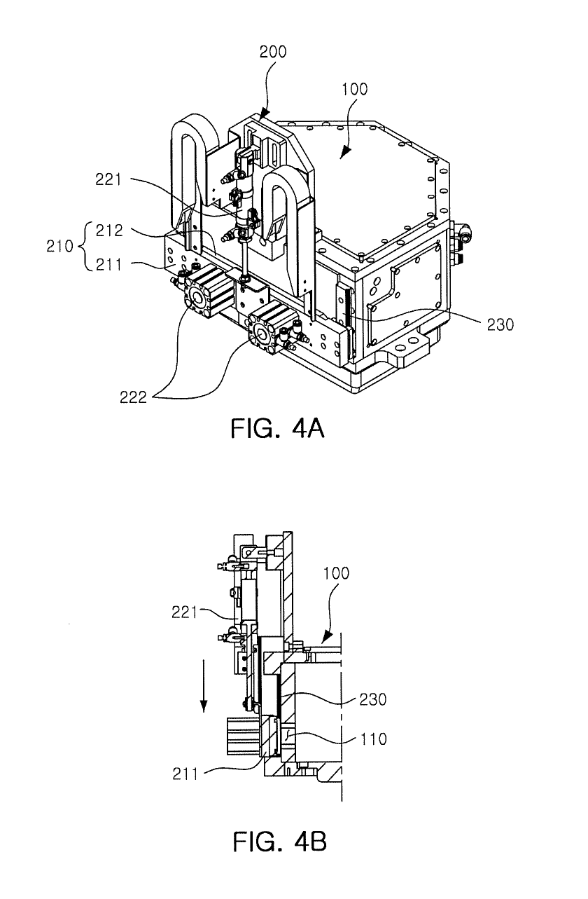

FIGS. 1 through 7 illustrate a wafer holder cleaning apparatus according to an embodiment of the inventive subject matter. FIG. 1 is a perspective view schematically showing a wafer holder cleaning apparatus according to an embodiment of the inventive subject matter. FIG. 2 is a cross-sectional view of FIG. 1, taken along line A-A. FIGS. 3A and 3B are a perspective view and a cross-sectional view schematically showing a state in which an entrance is opened by a door part, from FIG. 1. FIGS. 4A and 4B are a perspective view and a cross-sectional view schematically showing a state in which the entrance is closed by a door part, from FIG. 1.

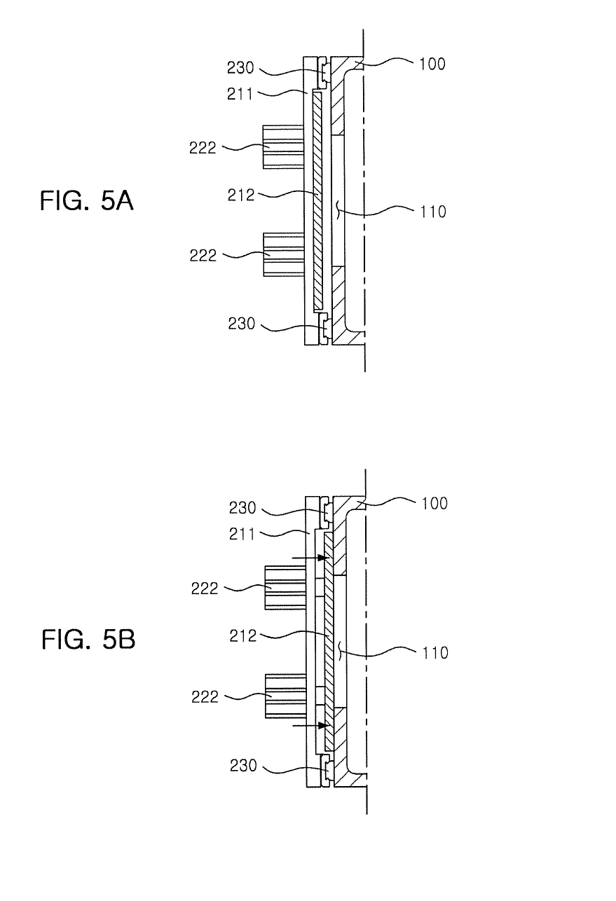

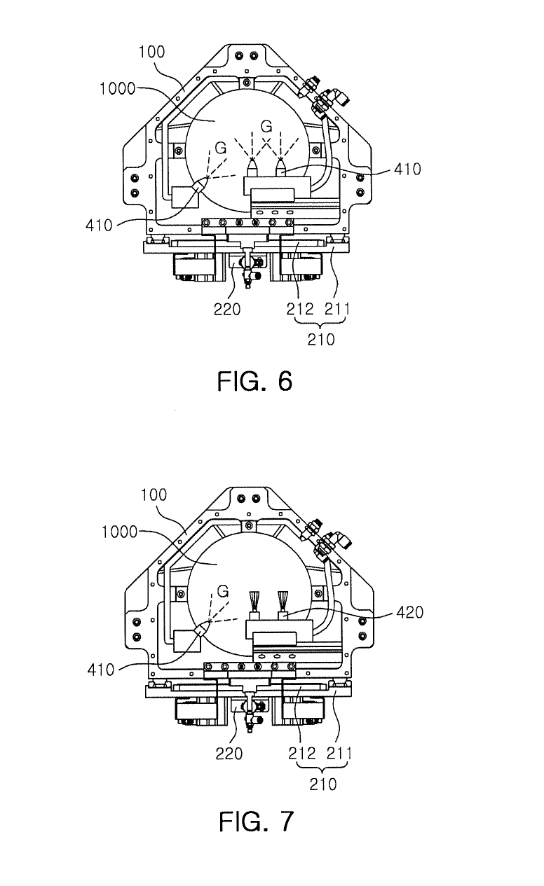

FIG. 5A is a plan view schematically showing a state before a second door closely contacts the entrance. FIG. 5B is a plan view schematically showing a state in which the second door closely contacts the entrance. FIGS. 6 and 7 are plan views schematically showing a cleaning part from FIG. 1.

Referring to FIGS. 1 through 7, a wafer holder cleaning apparatus 10 according to an embodiment of the inventive subject matter may include a housing part 100, a door part 200, a support part 300, and a cleaning part 400, and may further include a control part 500 and a ventilation part 600.

The housing part 100 may have a processing space surrounded by a plurality of side surfaces and having a predetermined size, and one of the side surfaces may be provided with an entrance 110 into and out of which wafer holders 1000 are carried.

The housing part 100 may be formed of a metallic material having high thermal and corrosion resistance as well as rigidity. In addition, the housing part 100 may be formed of a transparent material such that an internal state thereof may be readily apparent. The transparent material may include reinforced resin, reinforced glass or the like, for example.

The housing part 100 may be fixedly supported by a plurality of fixing units 120. In addition, a height of the housing part 100 may be adjusted by the fixing units 120.

The door part 200 may selectively open and close the entrance 110 of the housing part 100. The door part 200 may include doors 210 opening or closing the entrance 110, and actuators 220 moving the doors 210 to enable the entrance 110 to be opened or closed. In addition, the door part 200 may further include at least a pair of guide members 203 guiding the moving of the doors 210.

The pair of guide members 230 may individually have a structure of a bar-shaped rail having a predetermined length and may be provided on both sides of the entrance 210, respectively. In addition, the pair of guide members 230 may be disposed to be parallel to each other in a vertical direction.

The doors 210 may include a first door 211 vertically reciprocating along the pair of guide members 230 and a second door 212 provided on a surface of the first door 211 facing the housing part 100 and horizontally reciprocating.

The first door 211 may be disposed to face one side surface of the housing part 100 in which the entrance 110 is provided, and may be spaced apart from the one side surface by a predetermined distance. Further, the first door 211 may vertically reciprocate along the pair of guide members 230 so as to be parallel to the one side surface.

The first door 211 may be disposed in a position facing the entrance 110 through the vertical reciprocating movement. For example, the first door 211 may move upwardly along the guide members 230 to expose the entrance 110. In addition, the first door 211 may move downwardly along the guide members 230 and may be disposed in a position facing the entrance 110 to cover the entrance 110.

The second door 212 may be provided on the surface of the first door 211 facing the housing part 100 and vertically reciprocate together with the first door 211. In a state in which the first door 211 is disposed in a position facing the entrance 110 as in FIGS. 4A and 4B, the second door 212 may horizontally reciprocate with respect to the first door 211 as in FIGS. 5A and 5B. The second door 212 may closely contact the entrance 110 through the horizontal reciprocating movement to close the entrance 110 or may be spaced apart from the entrance 110 to open the entrance 110.

The actuators 220 may include a first actuator 221 connected to the first door 211 and enabling the first door 211 to be vertically reciprocated and a second actuator 222 connected to the second door 212 and enabling the second door 212 to be horizontally reciprocated.

The support part 300 may be provided within the housing part 100, and each wafer holder 1000 carried through the entrance 110 may be disposed on the support part 300 and supported thereby. The support part 300 may include a base 310 clamping or declamping the wafer holder 1000 and a driving unit 320 rotatably driving the base 310.

The base 310 may be a disk-like structure having a shape corresponding to that of the wafer holder 1000. The base 310 may fixedly clamp the wafer holder 100 thereto such that the wafer holder 1000 is not separated therefrom at the time of the rotatable driving thereof and may declamp the wafer holder 1000 such that the wafer holder 100 is carried out after the rotatable driving thereof.

The driving unit 320 may be connected to the base 310 through a rotational axis 321 and for example, include a rotary motor as a unit generating rotational force in order to rotatably drive the base 310 through power supplied from the outside.

The cleaning part 400 may clean the surface of the wafer holder 1000 disposed on the support part 300 so as to remove foreign objects or the like formed on the wafer holder 1000. The cleaning part 400 may include a spraying nozzle 410 spraying gas G onto the wafer holder 1000.

The spraying nozzle 410 may be provided in plural as illustrated in FIG. 6, and in this case, pressure of sprayed gas may be varied or a spraying range of gas may be differentially adjusted.

The spraying nozzle 410 may spray purge gas, for example, nitrogen (N₂) gas G onto the surface of the wafer holder 1000 to remove foreign objects from the surface of the wafer holder 1000. Specifically, the nitrogen gas G may be sprayed onto the surface of the wafer holder 1000 rotating at a predetermined speed on the support part 300 at a predetermined pressure to remove foreign objects adhered to the surface of the wafer holder 1000. The foreign objects may include particles parasitically deposited on the surface of the wafer holder 1000 during a process of depositing a semiconductor film on a surface of a wafer W placed on each wafer holder 1000.

Meanwhile, the cleaning part 400 may further include a brush 420 brushing the surface of the wafer holder 1000. That is, the cleaning part 400 may include the spraying nozzle 410 and the brush 420 as illustrated in FIG. 7, spray the nitrogen gas G through the spraying nozzle 410, and brush the surface of the wafer holder 1000 through the brush 420. It is obvious that the cleaning part 400 may only include the brush 420 except for the spraying nozzle 410. In this case, a single brush 420 or a plurality of brushes 420 may be provided.

The positions of the spraying nozzle 410 and the brush 420 may be adjusted to evenly clean the surface of the wafer holder 1000 overall. The positions of the spraying nozzle 410 and the brush 420 may be adjusted by hydraulic machinery, for example.

The ventilation part 600 may be provided in the housing part 100 to ventilate the interior of the housing part 100. When the nitrogen gas G is sprayed onto the surface of the wafer holder 1000 through the spraying nozzle 410, foreign objects adhered to the surface of the wafer holder 1000 may be suspended in the processing space, such that the processing space may be filled with the foreign objects and the nitrogen gas G. Since suspended foreign objects may be a contaminant source contaminating the interior of the housing part 100, the foreign objects may be discharged to the outside through the ventilation part 600 to prevent the interior of the housing part 100 from being contaminated.

The nitrogen gas G discharged to the outside, together with the foreign objects, may be reused through a filtering process.

The control part 500 may automatically control operations of the door part 200, the support part 300, the cleaning part 400 and the ventilation part 600. For example, the control part 500 may enable the doors 210 to be driven through the actuators 220 to open the entrance 110 of the housing part 100, and when the wafer holder 1000 is placed on the base 310 of the support part 300, the control part 500 may enable the doors 210 to be driven through the actuators 220 to close the entrance 110.

When it is confirmed that the entrance 10 is closed and the processing space of the housing part 100 is sealed, the base 310 may be rotatably driven by the driving unit 320 of the support part 300 and the nitrogen gas G may be sprayed onto the surface of the wafer holder 1000 through the spraying nozzle 410 of the cleaning part 400. By so doing, a cleaning operation may be performed on the wafer holder 1000.

When the cleaning operation is completed, the control part 500 may cease the operations of the cleaning part 400 and the support part 300 and drive the door part 200 to open the entrance 110, thereby enabling the wafer holder 1000 that has been cleaned to be carried out of the housing part 110. The ventilation part 600 may be operated during the cleaning operation or prior to the opening of the entrance 110 after the cleaning operation has been completed.

The process may be automatically undertaken by the control unit 500. The control part 500 may include an automatic equipment system including a computer as a component.

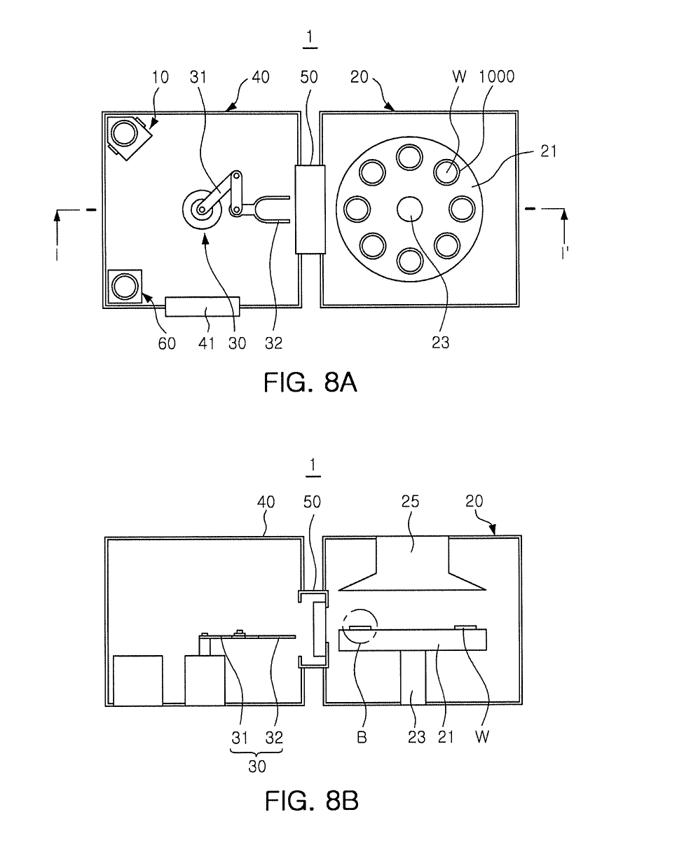

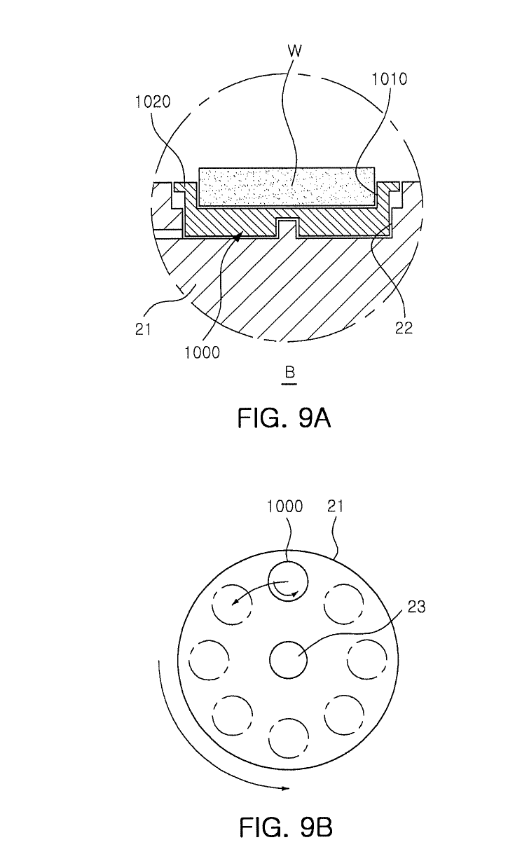

Referring to FIGS. 8 and 9, a film deposition system according to an embodiment of the inventive subject matter will be described. FIGS. 8A and 8B are a plan view and a cross-sectional view schematically showing a film deposition system according to an embodiment of the inventive subject matter. FIG. 9A is an enlarged cross-sectional view schematically showing portion B, from FIG. 8B. FIG. 9B is a plan view schematically showing a state in which a wafer holder of FIG. 9A rotates and revolves.

Referring to FIGS. 8 and 9, a film deposition system 1 according to an embodiment of the inventive subject matter may include a film deposition apparatus 20, a transfer apparatus 30, and the wafer holder cleaning apparatus 10, and may further include a chamber 40 receiving the transfer apparatus 30 therein.

The chamber 40 may receive the transfer apparatus 30 therein to isolate the transfer apparatus 30 from an external environment and may be connected to the film deposition apparatus 20 via a slit valve 50. The chamber 40 may receive the wafer holder cleaning apparatus 10 as well as the transfer apparatus 30 therein. That is, the transfer apparatus 30 and the wafer holder cleaning apparatus 10 may be received and disposed in the chamber 40 so as to be isolated from an external environment.

The chamber 40 may be formed of a transparent material such that an operator may readily observe an interior state thereof from the outside. The transparent material may include reinforced resin, reinforced glass or the like, for example.

One side of the chamber 40 may be provided with a gate 41, which the operator may access.

The film deposition apparatus 20, a type of a single crystal growth furnace for growing a semiconductor film, may include a chemical vapor deposition (CVD) apparatus, a metal organic chemical vapor deposition (MOCVD) apparatus, and the like. The film deposition apparatus 20 may allow a semiconductor film to be deposited and grown on the surface of the wafer W disposed within the film deposition apparatus 20, through reaction gas supplied from the outside.

The film deposition apparatus 20 may include a susceptor 21 on which a plurality of wafers W may be disposed, and a gas spray part 25 supplying the reaction gas to the plurality of wafers W. The susceptor 21 may be provided with a plurality of the wafer holders 1000 such that the plurality of wafers W may be disposed thereon.

Each wafer holder 1000 may include a satellite disk, for example, and may have a pocket portion recessedly formed in an upper surface thereof and having a shape corresponding to that of each wafer W such that the wafer W may be disposed thereon. The wafer holder 1000 may have a flange portion 1020 formed on an upper outside thereof so as to protrude along an edge thereof.

The susceptor 21 may have a plurality of grooves 22 formed in an upper surface thereof, and the wafer holders 1000 may be detachably mounted in the plurality of grooves 22. The grooves 22 may have a shape corresponding to that of the wafer holders 1000.

The plurality of wafer holders 1000 mounted in the plurality of grooves 22 may individually rotate (revolve) within the respective grooves 22 and may rotate (revolve) around a rotational axis 23 together with the susceptor 21 as the susceptor 21 rotates through the rotational axis 23.

The transfer apparatus 30 may carry the wafer holders 1000 out of the film deposition apparatus 20 and carry the wafer holders 1000 into the film deposition apparatus 20. The transfer apparatus 30 may include a robot arm 31 capable of being lengthened and shortened in a set direction as well as being rotated and a hand 32 provided on one end of the robot art 31 and gasping the wafer holders 1000.

Meanwhile, a wafer separation apparatus 60, as well as the transfer apparatus 30 and the wafer holder cleaning apparatus 10, may be further included in the chamber 40, and in this case, the wafer separation apparatus 60 may separate the wafers W from the wafer holders 1000 carried out of the film deposition apparatus 20.

The wafer separation apparatus 60 may separate the wafers w having a semiconductor film deposited thereon from the wafer holders 1000 before the wafer holders 1000 that have been carried out of the film deposition apparatus 20 due to the completion of the deposition process are transferred to the wafer holder cleaning apparatus 100, and may transfer the separated wafers W to the next process.

The wafer holders 1000 from which the wafers w have been removed may be transferred to the wafer holder cleaning apparatus 10 to remove foreign objects adhered to the surfaces thereof.

The wafer holder cleaning apparatus 10 may include the support part 300 on which the wafer holders 1000 that have been carried out through the transfer apparatus 30 are disposed. Further, the wafer holder cleaning apparatus 10 may include the housing part 100 having the support part 300 disposed therein and having the entrance 110 which the transfer apparatus 30 accesses in order carry the wafer holders 10 into and out of the housing part 100, the door part 200 selectively opening and closing the entrance 110, and the cleaning part 400 cleaning the surfaces of the wafer holders 1000.

The detailed descriptions of the wafer holder cleaning apparatus 10 are illustrated in FIGS. 1 through 7, and concrete operations thereof are explained therein, and thus, a detailed description of the wafer holder cleaning apparatus 10 will be omitted.

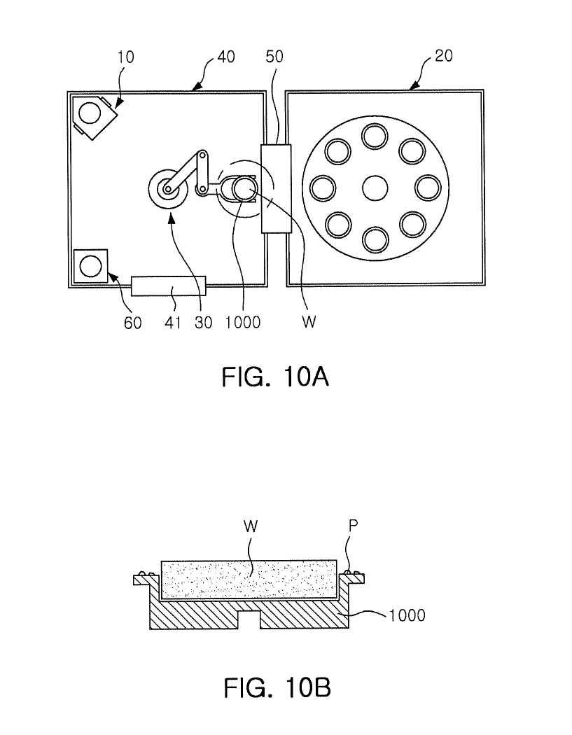

Referring to FIGS. 10 through 15, an operation of the film deposition system 1 according to an embodiment of the inventive subject matter will be described. FIGS. 10A through 15B are views schematically showing operational states of the film deposition system in a stepwise manner according to an embodiment of the inventive subject matter.

As in FIGS. 10A and 103, the robot arm 31 of the transfer apparatus 30 may extend inwardly of the film deposition apparatus 20 through the slit valve 50 provided between the chamber 40 and the film deposition apparatus 20, and the hand 32 thereof may grasp the wafer holders 1000.

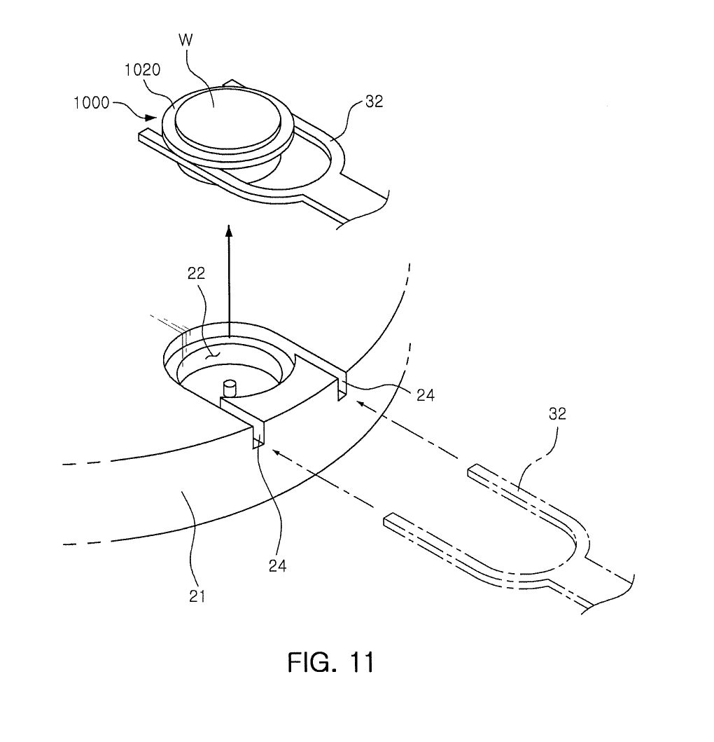

More specifically, as in FIG. 11, the susceptor 21 may have slits formed in an outer surface thereof in such a manner that they are connected to each groove 22 and have the hand 32 inserted therein. The hand 32 may be inserted in the slits 32 and grasp each wafer holder 1000 in such a manner that the flange portion 1020 of the wafer holder 1000 is supported thereby.

When the hand 32 grasps the wafer holder 1000, the robot arm 31 may be shortened to carry the wafer holder 1000 out of the film deposition apparatus 20. The surface of the wafer holder 1000 may have foreign objects P parasitically deposited thereon through a film deposition process.

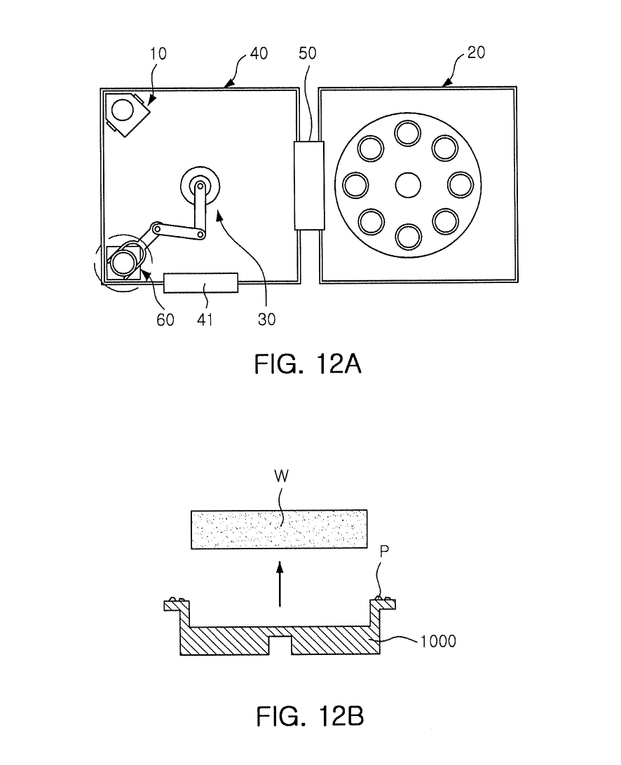

As in FIGS. 12A and 1213, the wafer holder 1000 carried out of the film deposition apparatus 20 may be transferred to the wafer separation apparatus 60 by the transfer apparatus 30.

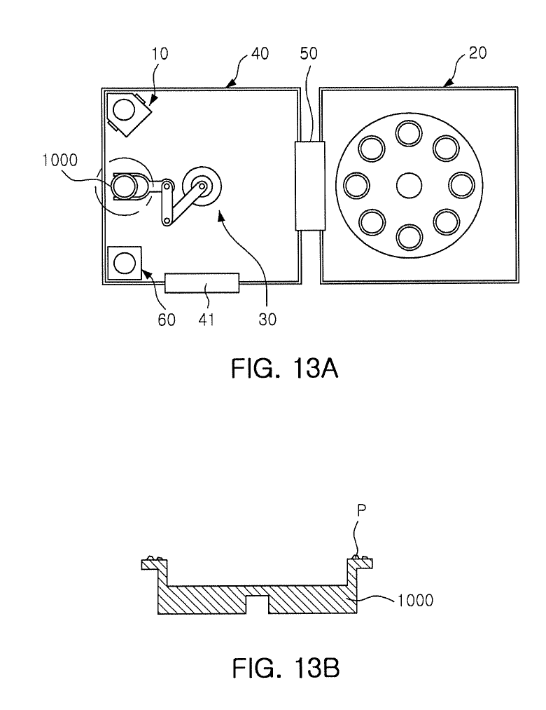

As in FIGS. 13A and 13B, the wafer holder 100 from which the wafer w has been removed may be transferred to the wafer holder cleaning apparatus 10 by the transfer apparatus 30 in order to remove the foreign objects P adhered to the surface thereof.

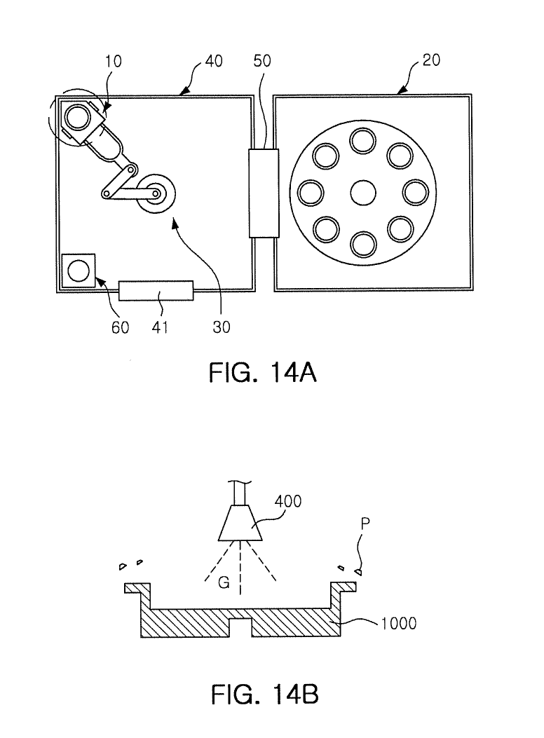

As in FIGS. 14A and 14B, the wafer holder 1000 to which the foreign objects P are adhered may be carried into the wafer holder cleaning apparatus 10 by the transfer apparatus 30, and the foreign objects P adhered to the surface thereof may be removed by gas spayed through the cleaning part 400 of the wafer holder cleaning apparatus 10.

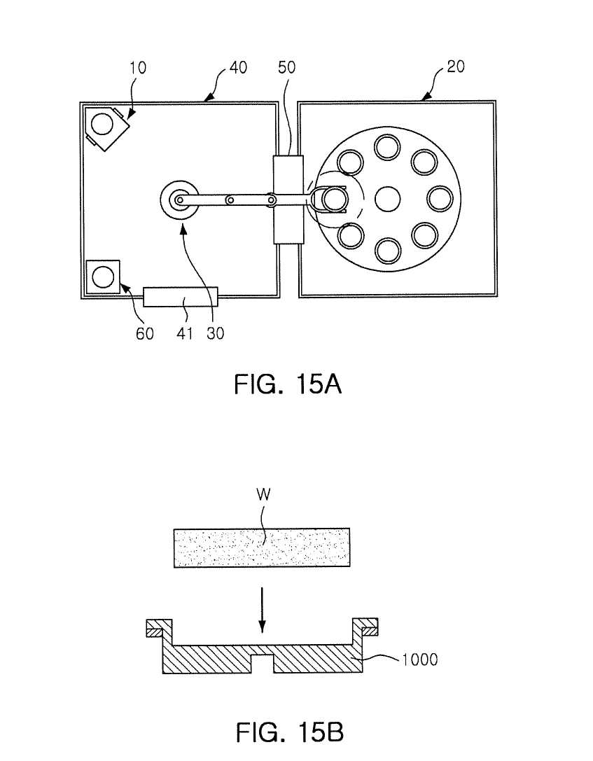

As in FIGS. 15A and 15B, after the cleaning process is completed, the wafer holder 1000 may be carried out of the wafer holder cleaning apparatus 10 by the transfer apparatus 30 and may be carried into the film deposition apparatus 20. Further, the wafer W for growing the film thereon may be disposed on the wafer holder 1000.

The processes of carrying the wafer holder 100 in and out may be continuously performed in a stepwise manner using the transfer apparatus 30.

As set forth above, according to embodiments of the invention, a wafer holder cleaning apparatus capable of automatically performing a previously manually performed cleaning operation on a wafer holder, and a film deposition system including the same, can be provided.

The various advantages and effects according to the inventive subject matter are not limited to the descriptions described above, and could be more readily understood in the detailed embodiments of the inventive subject matter.

While the inventive subject matter has been shown and described in connection with the embodiments, it will be apparent to those skilled in the art that modifications and variations can be made without departing from the spirit and scope of the invention as defined by the appended claims.

What is claimed is:

1. A wafer holder cleaning apparatus, comprising:
a housing part including an entrance into and out of which a wafer holder is carried;
a door part selectively opening and closing the entrance;
a support part provided within the housing part and having the wafer holder disposed thereon, the wafer holder being carried into the housing part through the entrance; and
a cleaning part cleaning a surface of the wafer holder.

2. The wafer holder cleaning apparatus of claim 1, wherein the cleaning part includes a spraying nozzle spraying gas onto the wafer holder.

3. The wafer holder cleaning apparatus of claim 2, wherein the spraying nozzle sprays nitrogen (N₂) gas onto the surface of the wafer holder.

4. The wafer holder cleaning apparatus of claim 1, wherein the cleaning part includes a brush brushing the surface of the wafer holder.

5. The wafer holder cleaning apparatus of claim 1, wherein the door part includes a door opening or closing the entrance and an actuator moving the door to enable the entrance to be opened or closed.

6. The wafer holder cleaning apparatus of claim 5, wherein the door part further includes at least a pair of guide members guiding the moving of the door.

7. The wafer holder cleaning apparatus of claim 1, wherein the support part includes a base clamping and declamping the wafer holder and a driving unit rotatably driving the base.

8. The wafer holder cleaning apparatus of claim 1, further comprising: a control part controlling operations of the door part, the support part, and the cleaning part.

9. The wafer holder cleaning apparatus of claim 1, further comprising: a ventilation part provided in the housing part and ventilating an interior of the housing part.
